(19) United States
(12) Patent Application Publication
(10) Pub. No.: US 2026/0246264 A1
(43) Pub. Date: Aug. 20, 2026

(54) TRANSIENT VOLTAGE SUPPRESSION DEVICE WITH CLAMPING CHARACTERISTIC

(71) Applicant: VISHAY GENERAL SEMICONDUCTOR, LLC, Malvern, PA (US)

(72) Inventors: Hui-Ying DING, Hexi District, Tianjin (CN); Wan-Lan CHIANG, Taipei (TW); Ming-Tai CHIANG, Taipei (TW); Hung-Ping TSAI, Da'an District, Taipei (TW); Chun-Ta LEE, Wenshan District, Taipei (TW)

(73) Assignee: VISHAY GENERAL SEMICONDUCTOR, LLC, Malvern, PA (US)

(21) Appl. No.: 19/161,053

(22) PCT Filed: Mar. 2, 2023
(86) PCT No.: PCT/CN2023/079249

§ 371 Date: Aug. 29, 2025

(51) Int. Cl. H02H 9/04; H02H 9/00

(52) U.S. Cl. CPC H02H 9/04; H02H 9/005

(57) ABSTRACT

A transient voltage suppression device includes a first transient voltage suppression diode having a first clamping characteristic, and a second snap back diode having a second clamping characteristic in series with the first transient voltage suppression diode. The first transient voltage suppression diode and the second snap back diode are electrically connected in parallel to a load.

### BACKGROUND

Conventional clamping protection schemes include the use of a transient voltage suppression (TVS) diode. A voltage surge occurs when a transient voltage increases the voltage across a load higher than the voltage that the load is designed to operate. This overvoltage can cause damage to the circuitry of the load. With the use of a TVS diode, when an overvoltage surge occurs in a circuit, the TVS diode clamps (i.e., limits) the voltage to a clamping voltage. However, utilizing a conventional TVS diode may not provide effective protection to protect a circuit from some overvoltages.

### BRIEF DESCRIPTION OF THE DRAWINGS

A more detailed understanding can be had from the following description, given by way of example in conjunction with the accompanying drawings wherein:

FIG. 1 is schematic of an example electronic circuit including transient voltage protection;

FIG. 2 is a graphical representation of the operation of a transient voltage suppression (TVS) diode;

FIG. 3 is a graphical representation of the operation of a snap-back diode;

FIG. 4 is a schematic of a TVS protection device in accordance with an example embodiment;

FIG. 5 is a block diagram of a stacked TVS protection device according to an example embodiment;

FIG. 6A shows an example assembly of a stacked TVS protection device;

FIG. 6B shows an example assembly of a stacked TVS protection device in accordance with an alternative example embodiment; and

FIG. 7 is a plan view of a side by side arrangement of a TVS protection device according to an example embodiment.

### DETAILED DESCRIPTION

An overvoltage in an electronic circuit can cause significant damage to the components in the electronic circuit. In order to protect an electronic circuit from overvoltages, protection may be employed. In some examples, protective circuitry, such as transient voltage suppression (TVS) diodes may be utilized in the circuitry to protect a load from an overvoltage.

A TVS diode operates by being connected in parallel with a load to protect across a source voltage. While a voltage level across the protected load maintains a level for operation of the load, the TVS diode does not operate. Operating voltage across the load allows for necessary operating current to flow through the load to operate.

However, when a transient voltage surge occurs, the TVS diode turns on to protect the protected load from the overvoltage. By turning on, the TVS diode clamps (limits) the voltage to a safe level to maintain a voltage across the load at a level where the load can continue to function while potentially damaging current is directed away from the load. An advantage of using a TVS diode is that a voltage transient surge can be prevented from damaging a circuit, while the circuit maintains operation at a safely clamped voltage level.

These TVS protection devices operate upon detecting an overvoltage surge to prevent damaging current from flowing through areas of circuitry that could be damaged, for example, by the increased current flow caused by the overvoltage. As mentioned, in one example, the protection devices clamp and limit the voltage across the protected circuitry. By clamping the voltage across the protected circuitry, excess current flow is rerouted to another path that prevents it from flowing through the circuitry and devices being protected, even though a clamped transient current continues to flow through the protected load.

A conventional TVS diode, such as will be described in more detail below includes a clamping characteristic that allows it to clamp the voltage effectively for a protected load to maintain a safe operating voltage. Another type of diode, referred to as a snap-back diode, which will also be described in further detail below, includes a different clamping characteristic that includes the advantage of a lower clamping ratio than a conventional TVS diode. However, once turned on, a snap-back diode may not turn off to allow operating power (i.e., voltage) to maintain operation of a protected load.

As mentioned above, one example for protecting a circuit is to utilize a conventional TVS diode. However, as mentioned above, utilizing a conventional TVS diode for voltage suppression may not result in adequate protection for a protected load. Accordingly, utilizing both a TVS diode and a snap-back diode together may provide enhanced circuit protection and performance. For example, by utilizing a conventional TVS diode connected in series with a snap-back diode, the clamping ratio (discussed in more detail below) of the combined protection scheme can approach 1.0, providing more effective protection by limiting any surge voltage to a safe level, while providing the proper operating voltage for the protected load to operate.

A method for circuit protection includes providing a first transient voltage suppression diode having a first clamping characteristic and a second snap back diode having a second clamping characteristic in series with the first transient voltage suppression diode. The first transient voltage suppression diode and the second snap back diode are electrically connected in parallel to a load.

A transient voltage suppression device includes a first transient voltage suppression diode having a first clamping characteristic, and a second snap back diode having a second clamping characteristic in series with the first transient voltage suppression diode. The first transient voltage suppression diode and the second snap back diode are electrically connected in parallel to a load.

A transient voltage suppression device includes a first transient voltage suppression diode having a first clamping characteristic, and a snap back diode having a second clamping characteristic in series with the first transient voltage suppression diode.

A transient voltage suppression method and device is described herein where the first transient voltage suppression diode has a voltage clamping ratio greater than 1.0.

A transient voltage suppression method and device is described herein where the clamping voltage of the first transient voltage suppression diode is higher than the breakdown voltage of the first transient voltage suppression diode.

A transient voltage suppression method and device is described herein where the second snap back diode has a voltage clamping ratio less than 1.0.

A transient voltage suppression method and device is described herein where the clamping voltage of the second snap back diode is less than the breakdown voltage of the second snap back diode.

A transient voltage suppression method and device is described herein where a clamping ratio of the first transient voltage suppression diode and the second snap back diode connected in series is substantially 1.0.

A transient voltage suppression method and device is described herein where a first terminal of the first transient voltage suppression diode is connected to a reference voltage, a first terminal of the second snap back diode is connected to a source voltage that is the source voltage of the load, and a second terminal of the first transient voltage suppression diode is connected to a second terminal of the second snap back diode.

A transient voltage suppression method and device is described herein where a first conductive layer is disposed upon a first side of the first transient voltage suppression diode.

A transient voltage suppression method and device is described herein where a second conductive layer is disposed upon a first side of the second snap back diode.

A transient voltage suppression method and device is described herein where the first conductive layer is soldered to the first side of the first transient voltage suppression diode and the second conductive layer is soldered to the first side of the second snap back diode.

A transient voltage suppression method and device is described herein where a solder layer connects a second side of the first transient voltage suppression diode to a second side of the second snap back diode.

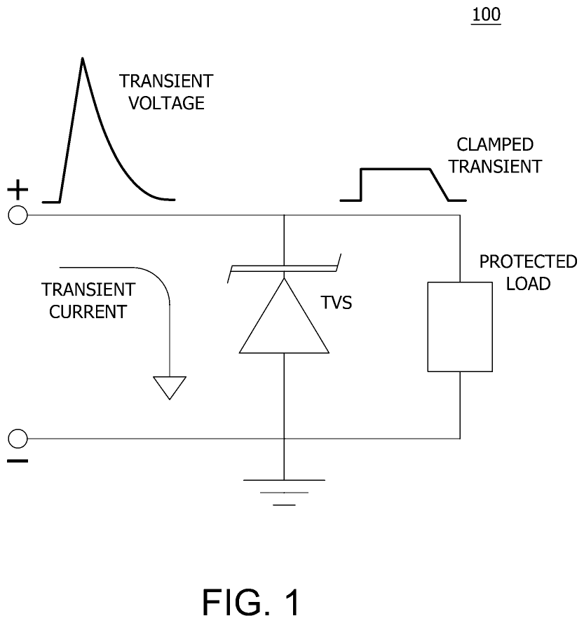

FIG. 1 is schematic of an example electronic circuit 100 including transient voltage protection. It is noted the electronic circuit 100 can be found in a number of devices that may experience a potential transient voltage surge, that if not limited, could cause damage to the circuitry (i.e., load). In one example, integrated circuits (ICs) may be provided protection from a damaging voltage surge caused by an overvoltage by a transient voltage protection device. These ICs may be utilized in any number of applications, such as computers, control units, and any other device that utilizes ICs that may experience a damaging overvoltage.

As can be seen in FIG. 1, the electronic circuit 100 includes a load component (protected component) that is connected across to a source voltage (indicated as a positive (+) source and a negative (−) source). A TVS diode is connected to the positive source similar to the protected load and to a reference voltage (e.g., ground). As mentioned above, the TVS diode is connected in parallel to the load component. In this manner, the voltage drop across the TVS diode is the same as the protected load. Accordingly, the TVS diode is able to operate to changes in voltage across the protected load since the TVS diode sees the same voltage.

Upon the transient voltage exceeding a threshold, the TVS diode shorts the positive terminal of the source to the reference voltage. Accordingly, a clamped transient current flows through the protected load. The excess transient current formed from the overvoltage (i.e., transient voltage) flows through the TVS diode to the reference (e.g., ground).

Accordingly, the overvoltage does not cause damage to the protected load by subjecting it to a potentially damaging voltage surge from the overvoltage. This provides protection from the overvoltage in a device containing the electronic circuit. In one example, as mentioned, potentially damaging excess transient current caused by the overvoltage is prevented from flowing through the protected load. Instead, this excess transient current produced by the overvoltage is routed away from the load, while allowing only clamped operating current to flow through the protected load.

The clamping of a TVS diode is explained in further detail below.

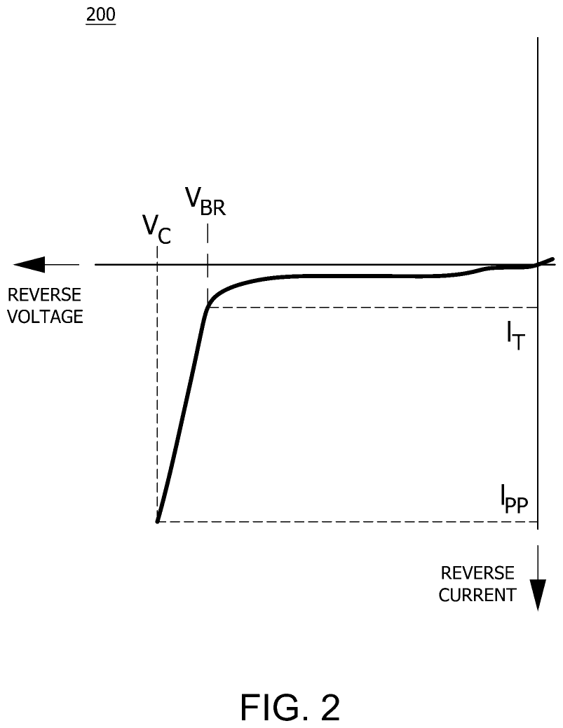

FIG. 2 is a graphical representation 200 of the operation of a TVS diode. As can be seen in FIG. 2, the horizontal axis shows the reverse voltage operation of the TVS diode and the vertical axis shows the reverse current operation of the TVS diode.

That is, FIG. 2 shows a current-voltage (I-V) curve of a TVS diode. The I-V curve shows the relationship between the voltage across the diode to the current flow. As can be seen in FIG. 2, IT is the current at the breakdown voltage (V_{BR}), and I_{PP} is the peak current at the clamping voltage (V_{C}). The breakdown voltage is the voltage at which the TVS diode operates (i.e., turns on) and begins to conduct current through itself. The clamping voltage is the voltage level at which the TVS diode clamps, or otherwise limits the voltage across the protected load.

The TVS diode includes a clamping ratio that is equal to the clamping voltage (V_{C}) divided by the breakdown voltage of the diode (V_{BR}). Accordingly, the clamping ratio may be calculated in accordance with the following equation:

$$Clamping Ratio ( CR ) = {V}_{C} / {V}_{BR} . \qquad Equation 1$$

As can be seen in FIG. 2, the clamping ratio of a TVS diode is greater than 1 (i.e., CR>1.0). By clamping the voltage at the clamped voltage, the TVS diode provides the advantage of overvoltage protection to the protected load. However, it is also possible that the protected load will be subjected to excess voltage due to the clamping voltage being higher than the breakdown voltage.

Referring back to FIGS. 1 and 2, the clamping ratio may be desired to be as close to 1.0 or at 1.0. When an overvoltage surge exceeds the TVS diode breakdown voltage, the TVS diode is turned on and the voltage across the TVS diode is maintained at the clamping voltage V_{C}. With a clamping ratio at 1.0, or substantially 1.0, the clamped voltage is as close to the breakdown voltage of the TVS diode. This provides for clamping of the voltage at the voltage which turns on the TVS diode as well as provides a safe operating voltage level for the protected load.

Because the protected load is also connected in parallel to the TVS diode, the clamping voltage V_{C} is the voltage across the protected load. Accordingly, the transient surge current flows through the TVS diode to ground while a clamped transient current flows through the protected load. In this manner, the load is protected from the higher surge current flowing through it causing potential damage. At the same time, the protected load continues to operate by having a clamped current as a result of the clamped voltage flow through it.

The breakdown voltage (V_{BR}) of the TVS diode needs to be high enough to sustain the normal operation of the protected load. Otherwise, a voltage that the protected load requires for operation would be clamped. In that case, the protected load would not be able to operate.

As shown in FIG. 2, the clamping voltage (V_{C}) of the TVS diode is higher than the breakdown voltage (V_{BR}) of the TVS diode. Accordingly, there is an amount of potential overvoltage that may occur across the protected load. In some cases, the protected load might be subjected to a voltage surge of 10%, 20% or more of the breakdown voltage. This level of voltage surge from an overvoltage may be potentially damaging since a protected load may not be rated for exposure to this level of overvoltage.

Since some devices (such as high grade integrated circuit (IC) chips) may not be able to withstand the surge overvoltage that a TVS diode would not be able to prevent, it might be beneficial to provide protection for voltages closer to the breakdown voltage. In this case, the surge voltage is limited to a safe level which allows the protected load to operate. For example, it may be desirable for the clamping ratio to be as close to 1.0 as possible. As described above, by having a clamping ratio as close to 1.0 as possible provides protection against a potentially damaging overvoltage from a voltage surge. In addition, the protected load continues to receive enough power to operate. In order to bring the clamping ratio of a TVS device closer to 1.0, the addition of a snap-back diode to a TVS diode in a protection circuit may be utilized.

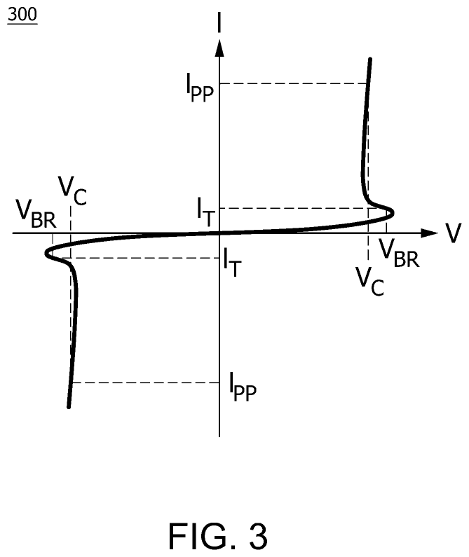

FIG. 3 is a graphical representation 300 of the operation of a snap-back diode. As can be seen in FIG. 3, the snap-back diode exhibits different characteristics than for the TVS diode graph shown in FIG. 2. For example, the clamping voltage is less than the breakdown voltage. Accordingly, the clamping ratio of the snap-back diode for example, is less than 1 (i.e., CR<1.0).

Referring back again to FIG. 1, and only for example, the operation of a snap-back diode could be described by replacing the TVS diode in FIG. 1 with a snap-back diode. The snap-back diode would clamp the overvoltage at V_{c} and operates (i.e., turns on) at V_{BR}.

As shown in FIG. 3, IT is the current at the breakdown voltage (V_{BR}), and I_{PP} is the peak current at the clamping voltage (V_{C}). The breakdown voltage is the voltage at which the snap-back TVS diode operates (i.e., turns on) and begins to conduct current through itself. The clamping voltage is the voltage level at which the snap-back diode clamps, or otherwise limits the voltage across the protected load.

From FIG. 3, it can be seen that the clamping voltage (V_{C}) is less than the breakdown voltage (V_{BR}). In this case the clamping ratio (CR) can be shown as being less than 1.0. Accordingly, the clamping voltage (V_{C}) is less than the normal operating voltage of the protected load.

Although the above may provide protection to a protected device, the clamping voltage being less than the breakdown voltage (V_{BR}) may cause the snap-back diode, once turned on, to fail to turn off as the voltage drop across the snap-back diode may remain less than the voltage drop across the protected load. In such case, there would not be any current flow through the protected load if the clamping voltage across the snap-back diode remains lower than the required operating voltage of the protected load.

That is, once turned on, the clamping voltage (V_{C}) being less than the breakdown voltage will not allow the snap-back diode to turn off. This would prevent needed power from being received by the protected load.

However, to overcome the disadvantages of the TVS diode, a snap back diode may be arranged electrically in series with the TVS diode across the source voltage shown in, for example, FIG. 1. That is, the TVS diode shown in FIG. 1 could be an incorporation of a combined TVS diode with behavior shown in FIG. 2, connected electrically in series with a snap-back diode, with the entirety of both diodes connected in parallel to the protected load. In this arrangement, a clamping ratio of 1.0 or very close thereof may be achieved, providing more effective protection of a protected device. These two diodes (conventional TVS diode and snap-back diode) are incorporated into a single device, for example.

Accordingly, the protection scheme of connecting both a conventional TVS diode in series with a snap-back diode leverages the characteristics of each type of diode. That is, the conventional TVS diode, which has a clamping ratio greater than 1.0, when combined in series with a snap-back diode, which has a clamping ratio of less than 1.0, together achieve a clamping ratio substantially 1.0, allowing for more effective protection of the protected load while also allowing the protected load to maintain operation.

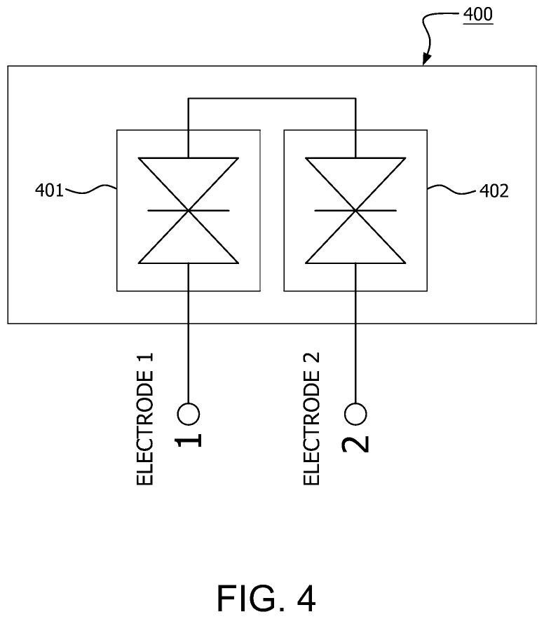

FIG. 4 is a schematic of a TVS protection device 400 (e.g., a surface mount TVS clamping diode including a series connection of a conventional TVS diode and a snap-back diode) in accordance with an example embodiment. As shown in FIG. 4, a first terminal of a first diode 401 (e.g., a conventional TVS diode) is connected to an electrode designated electrode 1. Electrode 1 may be connected to the positive source terminal shown in FIG. 1.

A first terminal of a second diode 402 (e.g., a snap-back diode) is connected to a second terminal of diode 401. A second terminal of the second diode 402 may be connected to a second electrode (designated electrode 2). Electrode 2 may then be connected to the reference terminal shown in FIG. 1.

In the circuit shown in FIG. 4, therefore, current flows from electrode 1 to electrode 2 through both diode 401 and diode 402. That is, diode 401 and diode 402 are connected in series with one other in relation to electrodes 1 and 2.

Accordingly, if electrode 1 is connected to the positive terminal of the circuit shown in FIG. 1, and electrode 2 is connected to the reference terminal in FIG. 1, current would flow through both diodes 401 and 402 from the positive terminal to the reference terminal, in parallel to the protected load shown in FIG. 1. In this manner, the diode pair of diode 401 and diode 402 act as a transient voltage suppression circuit protecting the protected load in FIG. 1.

As mentioned previously, by connecting the entire TVS protection device 400 in parallel with the protected load, it is subjected to the same voltage levels as the protected load. In such case, the TVS protection device 400 operates based upon an overvoltage that would be across the protected load in order to turn it on.

It should be noted that although in an example embodiment, the TVS diode is depicted as diode 401 and the snap-back diode is depicted as diode 402, the diodes can be connected in series in any order. That is, diode 401 can be a snap-back diode and diode 402 can be a TVS diode. Additionally, the physical arrangement of diode 401 and diode 402 can be provided in varying forms.

The arrangement of diode 401 and diode 402 include a clamping ratio close to or equal to 1.0 (i.e., CR=1.0). Having a clamping ratio substantially 1.0 provides more effective protection to the protected load than a clamping ratio of greater than 1.0 or less than 1.0.

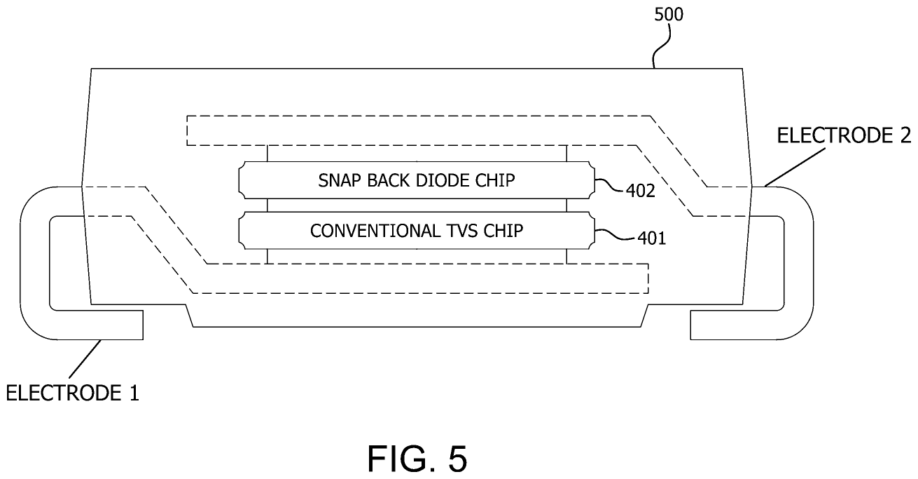

FIG. 5 is a block diagram of a stacked TVS protection device 500 according to an example embodiment. That is, in FIG. 5, the diode pair of diode 401 and diode 402 are physically arranged one on top of the other in a chip package.

Referring to FIGS. 4 and 5, electrode 1 is shown connected to a first side and terminal of a conventional TVS chip (e.g., diode 401). The first side and terminal may be a bottom side of the diode 401. Electrode 2 is shown as connected to a first side of a snap-back diode chip (e.g., diode 402). The first side and terminal of the snap-back diode chip may be a top side of diode 402 in this example.

A second side of diode 401 is then connected to a second side of diode 402. In the example shown in FIG. 5, the second side of diode 401 may be a top side of diode 401 and the second side of diode 402 may be a bottom side of the diode 402.

In the above manner, a series circuit is formed between electrode 1, diode 401, diode 402 and electrode 2. Again, referring to FIG. 1, electrode 1 may be connected to the positive terminal of the circuit shown in FIG. 1 and electrode 2 may be connected to the reference terminal of the circuit shown in FIG. 1. Accordingly, the series circuit formed between electrode 1 and electrode 2 operates in parallel with the protected load shown in FIG. 1.

By connecting diode 401 and diode 402 in series, the pair is subjected to the same voltage as the protected load in order to protect it. Further, the same current will flow through the pair of diodes 401 and 402 by virtue of their series connection.

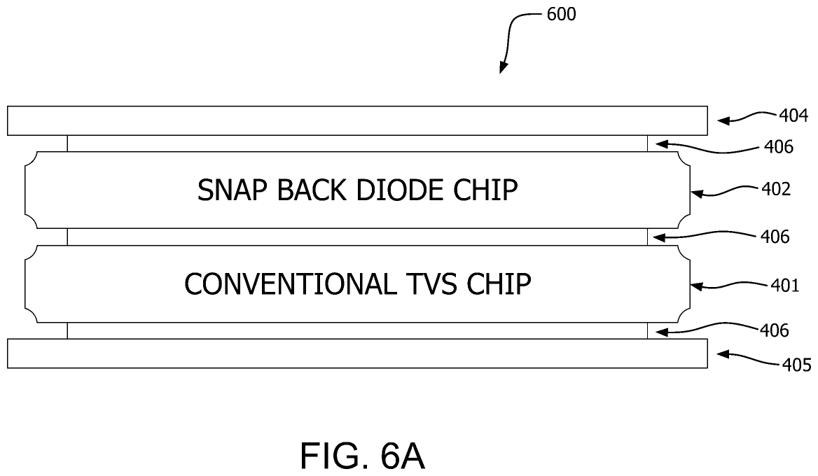

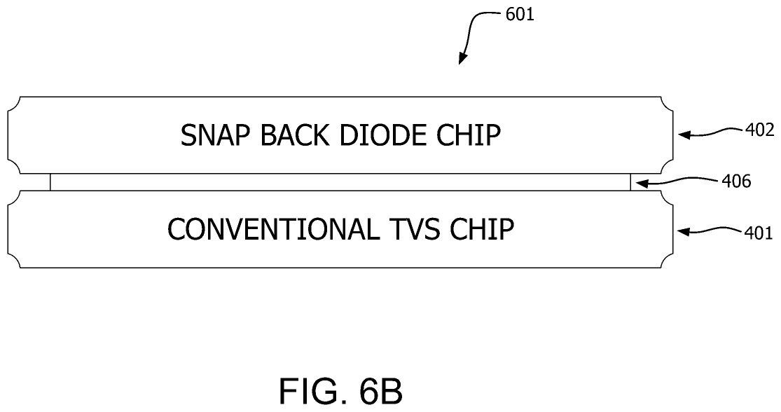

FIG. 6A shows an example assembly of a stacked TVS protection device 600 in accordance with an example embodiment. For example, FIG. 6A shows an example configuration and structural assembly of the diode shown in FIG. 5. A first conductive layer (e.g., a copper slug) 404 may be soldered 406 to the snap back diode chip 402 on the first side of the snap-back diode chip 402.

A second conductive layer 405 (e.g., another copper slug) may be soldered 406 to the first side of the conventional TVS chip 401. An additional solder layer 406 may be provided between the conventional TVS chip 401 and the snap-back diode chip 402 connected the second side of the conventional TVS chip 401 and the second side of the snap-back diode chip 402. Again, it should be noted that the order of the chips may vary. That is, although the conventional TVS chip 401 is shown on a bottom side of the assembly and the snap-back diode chip 402 is shown on the top side, the two chips could exchange places.

FIG. 6B shows an example assembly of a stacked TVS protection device 601 in accordance with an alternative example embodiment. As shown in FIG. 6B, the first conductive layer 404, the second conductive layer 405 and the solder layers 406 that connect them to their respective chips 401 and 402, are not provided.

Further, as mentioned above, the physical arrangement of the conventional TVS chip 401 and the snap-back diode chip 402 may vary. For example, rather than being stacked one on top of the other, the conventional TVS chip 401 and the snap-back diode chip 402 could be physically arranged side by side.

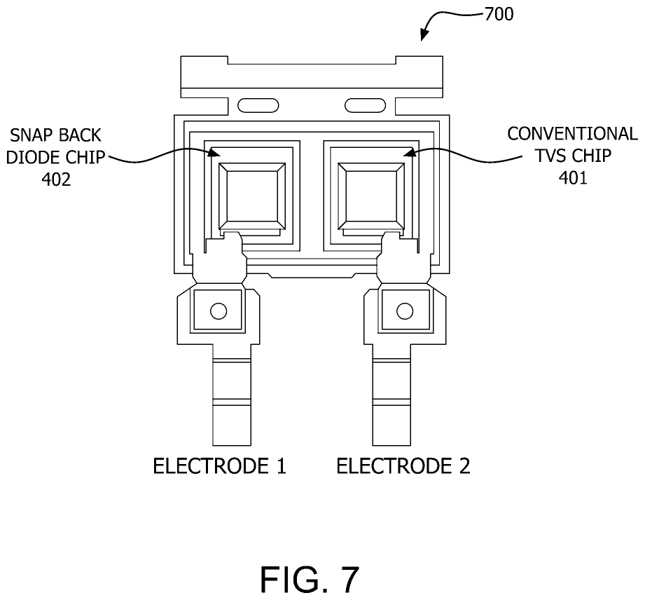

FIG. 7 is a plan view of a side by side arrangement 700 of a TVS protection device according to an example embodiment. In this arrangement, the conventional TVS chip 401 and the snap-back diode chip 402 are arranged side by side. Further electrode 1 is shown as being connected to a first terminal of the snap back diode chip 402 while electrode 2 is shown as being connected to a first terminal of the conventional TVS chip 401. The second terminals of the conventional TVS chip 401 and the snap-back diode chip 402 are connected together, similarly to FIG. 5.

In such an arrangement, electrode 1 may be connected to the positive terminal of the circuit shown in FIG. 1 while electrode 2 may be connected to the reference terminal shown in FIG. 1. Again, this forms a series circuit from electrode 1 to electrode 2 through the conventional TVS chip 401 and the snap-back diode chip 402.

Again, as mentioned above, the example shown refers to electrode 1 as being connected to the positive terminal of FIG. 1 and electrode 2 connected to the reference terminal of FIG. 1. However, it should be noted that in an alternate arrangement, electrode 2 may be connected to the positive terminal of the circuit shown in FIG. 1 and electrode 1 may be connected to the reference terminal of FIG. 1.

Similar to the arrangement shown in FIG. 5, therefore, the circuit formed between electrode 1 through the diodes 401 and 402 to electrode 2 are a series circuit. Moreover, the series circuit formed from electrode 1 to electrode 2 operates in parallel to the circuit through the protected load in FIG. 1, for example.

It should be understood that many variations are possible based on the disclosure herein. Although features and elements are described above in particular combinations, each feature or element can be used alone without the other features and elements or in various combinations with or without other features and elements.

1-20. (canceled)

21. A method for circuit protection, comprising:
providing a transient voltage suppression diode having a first clamping characteristic; and
providing a snap back diode having a second clamping characteristic in series with the transient voltage suppression diode;
wherein the transient voltage suppression diode and the snap back diode are electrically connected in parallel to a load,
wherein a clamping ratio of the transient voltage suppression diode and the snap back diode connected in series is substantially 1.0, and
wherein the clamping ratio is a ratio between a clamping voltage and a breakdown voltage.

22. The method of claim 21, wherein the transient voltage suppression diode has a voltage clamping ratio greater than 1.0.

23. The method of claim 22, wherein the clamping voltage of the transient voltage suppression diode is higher than the breakdown voltage of the transient voltage suppression diode.

24. The method of claim 21, wherein the snap back diode has a voltage clamping ratio less than 1.0.

25. The method of claim 24, wherein the clamping voltage of the snap back diode is less than the breakdown voltage of the snap back diode.

26. The method of claim 21, wherein a first terminal of the transient voltage suppression diode is connected to a reference voltage, a first terminal of the snap back diode is connected to a source voltage that is the source voltage of the load, and a second terminal of the transient voltage suppression diode is connected to a second terminal of the snap back diode.

27. A transient voltage suppression device, comprising:
a transient voltage suppression diode having a first clamping characteristic; and
a snap back diode having a second clamping characteristic in series with the transient voltage suppression diode;
wherein the transient voltage suppression diode and the snap back diode are electrically connected in parallel to a load,
wherein a clamping ratio of the transient voltage suppression diode and the snap back diode connected in series is substantially 1.0, and
wherein the clamping ratio is a ratio between a clamping voltage and a breakdown voltage.

28. The device of claim 27, wherein the transient voltage suppression diode has a voltage clamping ratio greater than 1.0.

29. The device of claim 28, wherein the clamping voltage of the transient voltage suppression diode is higher than the breakdown voltage of the transient voltage suppression diode.

30. The device of claim 27, wherein the snap back diode has a voltage clamping ratio less than 1.0.

31. The device of claim 30, wherein the clamping voltage of the snap back diode is less than the breakdown voltage of the snap back diode.

32. The device of claim 27, wherein a first terminal of the transient voltage suppression diode is connected to a reference voltage, a first terminal of the snap back diode is connected to a source voltage that is the source voltage of the load, and a second terminal of the transient voltage suppression diode is connected to a second terminal of the snap back diode.

33. The device of claim 32, wherein the transient voltage suppression diode is physically arranged above the snap back diode.

34. The device of claim 32, wherein the transient voltage suppression diode is physically arranged adjacent to the snap back diode.

35. A transient voltage suppression device, comprising:
a transient voltage suppression diode having a first clamping characteristic; and
a snap back diode having a second clamping characteristic in series with the transient voltage suppression diode;
wherein a clamping ratio of the transient voltage suppression diode and the snap back diode connected in series is substantially 1.0, and wherein the clamping ratio is a ratio between a clamping voltage and a breakdown voltage.

36. The device of claim 35, further comprising a first conductive layer disposed upon a first side of the transient voltage suppression diode.

37. The device of claim 36, further comprising a second conductive layer disposed upon a first side of the snap back diode.

38. The device of claim 37, wherein the first conductive layer is soldered to the first side of the transient voltage suppression diode and the second conductive layer is soldered to the first side of the snap back diode.

39. The device of claim 38, further comprising a solder layer connecting a second side of the transient voltage suppression diode to a second side of the snap back diode.
